(19) United States
(12) Patent Application Publication
(10) Pub. No.: US 2014/0095090 A1
(43) Pub. Date: Apr. 3, 2014

(54) RESIDUAL BATTERY CAPACITY ESTIMATION SYSTEM THAT ADDS TWO MUTUALLY PERPENDICULAR COMPONENTS AND THE METHOD THEREOF

(71) Applicant: METAL INDUSTRIES RESEARCH & DEVELOPMENT CENTRE, Kaohsiung City (TW)

(72) Inventors: Sheng Wei CHEN, Kaohsiung City (TW); Kuan Yuen LIAO, Kaohsiung City (TW); Wen Jiun LIU, Kaohsiung City (TW); Kai Chung LIU, Kaohsiung City (TW); Li Hsuan CHUNG, Kaohsiung City (TW)

(73) Assignee: METAL INDUSTRIES RESEARCH & DEVELOPMENT CENTRE, Kaohsiung City (TW)

(21) Appl. No.: 13/727,466

(22) Filed: Dec. 26, 2012

(30) Foreign Application Priority Data
Sep. 28, 2012 (TW) 101135682

(51) Int. Cl. G01R 31/36; G06F 17/00

(52) U.S. Cl. CPC G01R 31/3624; G06F 17/00
USPC 702/63

(57) ABSTRACT

A residual battery capacity estimation system that adds two mutually perpendicular components and the method thereof are provided. The mechanism detects the battery voltage, current and temperature as the sensing parameters, and uses the preset electrical characteristic parameters and capacity change to look up a table for the battery dynamic internal resistance component. The mechanism uses the sensing parameters and the Coulomb counting method to calculate the component of the battery Coulomb counting charge. Afterwards, the battery dynamic internal resistance component and the battery Coulomb counting capacity component are then added to calculate the actual residual power of the battery. The mechanism achieves the goal of increasing the accuracy in estimating the battery residual power.

### BACKGROUND

1. Technical Field

The invention relates to a residual battery capacity estimation system and the method thereof. In particular, the invention relates to a residual battery capacity estimation system that uses vectors to obtain the actual residual capacity of the battery by adding two mutually perpendicular components and the estimation method thereof.

2. Related Art

In recent years, with the popularity of mobile devices, how to accurately estimate remaining battery power has become one of the problems that manufacturers want to solve.

In general, the traditional estimation method of residual battery capacity utilizes a lookup table. For example, the voltage is used to find the corresponding residual capacity estimate. However, since the battery voltage is affected by the discharge current. That is, the variation in the discharge current simultaneously affects the estimation of the residual battery charge. As a result, the estimated residual capacity of the battery fluctuates with the battery voltage. Therefore, there is a problem in accurately estimating the residual battery capacity.

In view of this, some vendors propose the Coulomb counting method to estimate the residual battery capacity. The Coulomb counting method is also known as the Ampere-Hour law. Based on the principle of energy conservation, the residual battery capacity is the difference between the residual capacity from the previous charge and the amount of discharge, or the residual capacity after the previous discharge plus the charge. Since the Coulomb counting method needs to continually perform accumulating or decreasing operations. Thus, errors also continually increase. After a long time of accumulation, the accuracy of estimation will be substantially affected. Besides, the setting of the initial capacity is another source of error for the Coulomb counting method. As a result, the charged power is not the maximum capacity. Consequently, the above method still cannot effectively solve the problem of poor accuracy in residual battery capacity estimation.

Further, some others also propose to use two methods to estimate the residual battery capacity, e.g., using the Coulomb integral method and the voltage look-up table method. After obtaining the two residual capacity estimates, different weights are incorporated to obtain a sum residual capacity value. For example, one can use the formula “SOC=αSOC_{c}+(1−α)SOC_{ν}” to add the two residual capacity values obtained from the Coulomb integral method (SOC_{c} in the formula) and the voltage look-up table method (SOC_{ν} in the formula). Here“α” is the default weight. This method can improve the accuracy in estimating the residual battery capacity. However, the weight value “α” in this method cannot dynamically change. The residual capacity value thus determined is accurate only within a certain interval, but inaccurate elsewhere. Therefore, this estimation method still cannot effectively solve the problem of poor accuracy in residual battery capacity estimation.

In summary, the prior art has long the problem of power accuracy in estimating the residual battery capacity. It is necessary to provide an improved means to solve this problem.

### SUMMARY

In view of the foregoing, the invention discloses a residual battery capacity estimation method that adds two mutually perpendicular components and the method thereof.

The disclosed system includes: a storage module, a sensing module, a calculating module, an integrating module and an estimating module. The storage module stores electrical characteristic parameters and a capacity variation lookup table. The sensing module senses the battery voltage, current and temperature to generate sensing parameters. The calculating module continuously uses the sensing parameters to compute a battery dynamic internal resistance indicator, and continuously uses the battery dynamic internal resistance indicator to look up in the capacity variation lookup table to generate the battery dynamic internal resistance capacity component. The integrating module uses the Coulomb counting method and the sensing parameters to generate a battery Coulomb counting capacity component. The estimating module adds up the battery dynamic internal resistance capacity component and the battery Coulomb counting capacity component to calculate the actual residual capacity of the battery.

The disclosed method includes the steps of: storing electrical characteristic parameters and a capacity variation lookup table in advance; detecting battery voltage, current, and temperature to generate sensing parameters; continuously using the sensing parameters to calculate a battery dynamic internal resistance indicator, and continuously using the battery dynamic internal resistance indicator to find a battery dynamic internal resistance capacity component from the capacity variation lookup table; using the sensing parameters and the Coulomb counting method to generate a battery Coulomb counting capacity component; combining the battery dynamic internal resistance capacity component and the battery Coulomb counting capacity component to calculate the actual residual battery capacity.

As described above, the invention differs from the prior art in that the invention detects and takes the battery voltage, current and temperature as the sensing parameters. Using predetermined electrical characteristic parameters and the capacity variation lookup table, the invention finds the battery dynamic internal resistance capacity component. The invention also uses the sensing parameters to find the battery Coulomb counting capacity component using the Coulomb counting method. Finally, the invention combines the battery dynamic internal resistance capacity component and the battery Coulomb counting capacity component to obtain the actual residual battery capacity.

Using the above-mentioned means, the invention achieves the objective of increasing the accuracy in estimating the residual battery capacity.

### BRIEF DESCRIPTION OF THE DRAWINGS

The invention will become more fully understood from the detailed description given herein below illustration only, and thus is not limitative of the present invention, and wherein:

FIG. 1 is a system block diagram of the disclosed residual battery capacity estimation system that adds two mutually perpendicular components;

FIG. 2 is a flowchart of the disclosed method that adds two mutually perpendicular components to estimate the residual battery capacity;

FIG. 3 is a schematic view of using the battery dynamic internal resistance indicator to generate the battery dynamic internal resistance capacity component according to the invention;

FIGS. 4 and 5 are schematic views of weight processing for intermediate discharge C values according to the invention;

FIG. 6 is a schematic view of defining the residual battery capacity percentage according to the invention; and

FIG. 7 shows how the invention calculates the residual battery capacity percentage.

### DETAILED DESCRIPTION

The present invention will be apparent from the following detailed description, which proceeds with reference to the accompanying drawings, wherein the same references relate to the same elements.

Before describing the disclosed system and method, we first define terms used herein. The battery dynamic internal resistance indicator is a value computed based on the variation of the internal resistance (which varies with the voltage of the battery while charging or discharging, e.g., the internal resistance increases as the battery charges/discharges). This value (battery dynamic internal resistance indicator) is used with a lookup table to find the corresponding capacity, thereby generating the battery dynamic internal resistance capacity component, to be detailed later with the accompanying figures. In practice, the formula for the battery dynamic internal resistance indicator is “(reference voltage−closed circuit voltage)*α/(reference voltage+/β*closed circuit voltage)”, where “α” is a magnification parameter. Since the reference voltage minus the closed circuit voltage is usually the minimum, it is multiplied by the magnification parameter for the convenience of calculations. “β” is a parameter related to the type and number of batteries connected in series. During the calculation process, the detected voltage value is continuously plugged into the closed circuit voltage the formula to obtain the battery dynamic internal resistance indicator. This calculation can remove the effect of the current factor. It should be mentioned that the invention is not restricted to the above-mentioned particular method of generating the battery dynamic internal resistance indicator. Any method that uses the reference voltage and the closed circuit voltage to continuously computing the battery dynamic internal resistance indicator should be included in the invention.

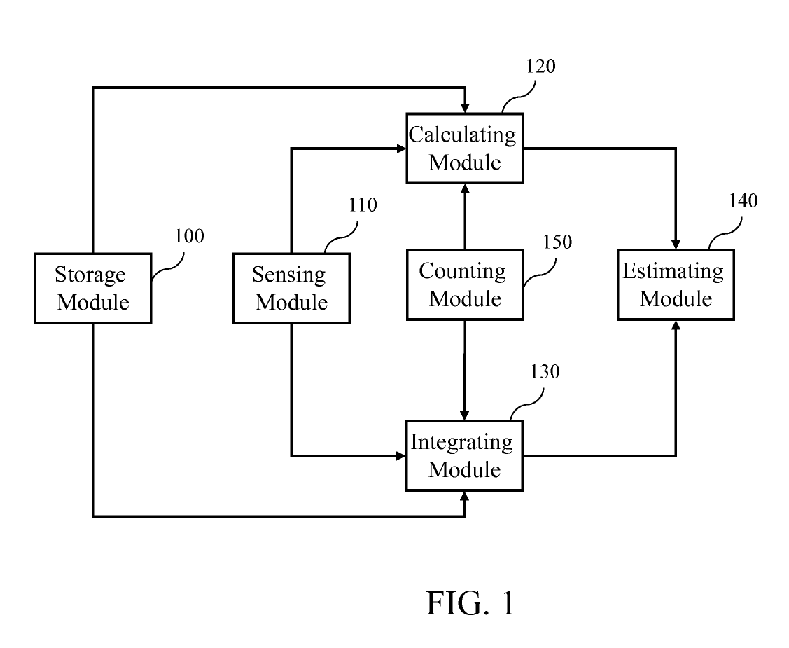

Please refer to FIG. 1. FIG. 1 is a system block diagram of the disclosed residual battery capacity estimation system that adds two mutually perpendicular components. The system includes: a storage module 100, a sensing module 110, a calculating module 120, an integrating module 130, and an estimating module 140. The storage module 100 stores in advance electrical characteristic parameters and a capacity variation lookup table. The electrical characteristic parameters include material properties of the battery core, number of battery sets in series, sizes of battery sets, reference voltage, magnification rate, temperature correction parameter, types of battery, number of batteries in series, etc. The capacity variation lookup table is a lookup table with different discharge currents and the corresponding capacities. For example, the table lists the discharge currents 0.5 C, 1 C, 1.5 C, 2 C to the maximum current and corresponding capacities of the battery. The interval of the discharge currents can be further divided according to practical needs into 0.25 C, 0.5 C, 0.75 C, . . . , to the maximum current or use an arithmetic series for the discharge currents of the battery set. In practice, the storage module 100 can further store a lookup table of temperatures and the corresponding capacity of the battery set and Coulomb counting correction parameters for correcting the computed battery Coulomb counting capacity component. Besides, the electrical characteristic parameters, the capacity variation lookup table, and the temperature variation lookup table can be stored beforehand in read-only memory (ROM), electrically erasable programmable read-only memory (EEPROM) or flash ROM.

The sensing module 110 detects the battery voltage, current, and temperature to generate sensing parameters. For example, a voltage sensor is used to detect the closed circuit voltage of the battery. A current sensor is used to detect the closed circuit current and the discharge current. A temperature sensor is used to detect the battery temperature. These detected values are then used as the sensing parameters. In practice, the sensing parameters can be stored in EEPROM or flash memory.

The calculating module 120 continuously uses the sensing parameters and the predetermined electrical characteristic parameters to compute a battery dynamic internal resistance indicator, which as defined before has the formula “(reference voltage+closed circuit voltage)*α/(reference voltage+β*closed circuit voltage)”, where “α” is a magnification parameter and “β” is a parameter related to the type and number of batteries connected in series. By setting “α” and “β” parameters, the battery dynamic internal resistance indicator can be controlled between 0 and 100. The computation of the battery dynamic internal resistance indicator is done by continuously plugging the detected voltage into the closed circuit voltage. The computed battery dynamic internal resistance indicator is continuously compared with the initial battery dynamic internal resistance indicator. The computation can cancel out the current factor effect. Afterwards, the calculating module 120 uses the battery dynamic internal resistance indicator to look up and generate the battery dynamic internal resistance capacity component. For example, the capacity variation lookup table is provided with the correspondence between various different discharge currents (in units of C) and the battery dynamic internal resistance indicators along with the corresponding capacities. For example, at 1 C, the battery dynamic internal resistance indicator of “64” corresponds to the capacity of “92%”, the battery dynamic internal resistance indicator of “80” corresponds to the capacity of “97%”, and the battery dynamic internal resistance indicator of “100” corresponds to the capacity of “100%”. Therefore, during the lookup process, the calculating module 120 can use the calculated battery dynamic internal resistance indicator to find the corresponding capacity from the capacity variation lookup table to generate the battery dynamic internal resistance capacity component. The generation method of this component will be explained with accompanying figures later.

The integrating module 130 uses the sensing parameters to generate a Coulomb counting capacity component with the Coulomb counting method, such as “Q(t)=Q₀+(∫ₜ_{₀}^{t}idt)”, where “Q₀” is the initial charge before discharge time “t₀” computed from the capacity variation lookup table. The discharge current “i” is negative. Dividing “Q(t)” computed for time “t” by the total charge capacity “Q_{Full}”, one obtains the capacity percentage “j”. The value “j” can be the horizontal component, i.e., the Coulomb counting capacity component. Since the Coulomb counting method and the component conversion belong to the prior art, they are not further described herein.

The estimating module 140 adds the battery dynamic internal resistance capacity component and the battery Coulomb counting capacity component to compute the actual residual battery capacity. For example, suppose the battery dynamic internal resistance capacity component is “\vec{V}” and the battery Coulomb counting capacity component is “\vec{C}”. Then the formula for synthesizing the two components is “\vec{SOC}=\vec{V}+\vec{C}”. Since the vector arithmetic belongs to the prior art, it is not further described herein.

Besides, a counting module 150 can be included to store and compare the cycle count of the battery as a battery aging parameter. The battery aging parameter can be stored in the electrical characteristic parameters of the storing module 100. The calculating module 120 and the integrating module 130 use the battery aging parameter and the battery temperature stored in the sensing parameters and the temperature variation lookup table in the storage module 100 to correct the battery dynamic internal resistance capacity component. At the same time, the Coulomb counting correction parameter in the storage module 100 is used to correct the battery Coulomb counting capacity component. Take the correction of the battery dynamic internal resistance capacity component as an example. The detected battery temperature and the discharge current are used to find in the temperature variation lookup table the weight for the corresponding battery dynamic internal resistance indicator, thereby correcting the computed battery dynamic internal resistance component. For example, suppose battery temperature is “40° C.” and the discharge current is “1 C”. The battery dynamic internal resistance component is “75”. When the corresponding weight of “5” is obtained, the weight and the battery dynamic internal resistance component “75” are computed to generate the corrected battery dynamic internal resistance capacity component, such as “70”. This can effectively correct the effects of the temperature and the cycle count on the residual battery capacity.

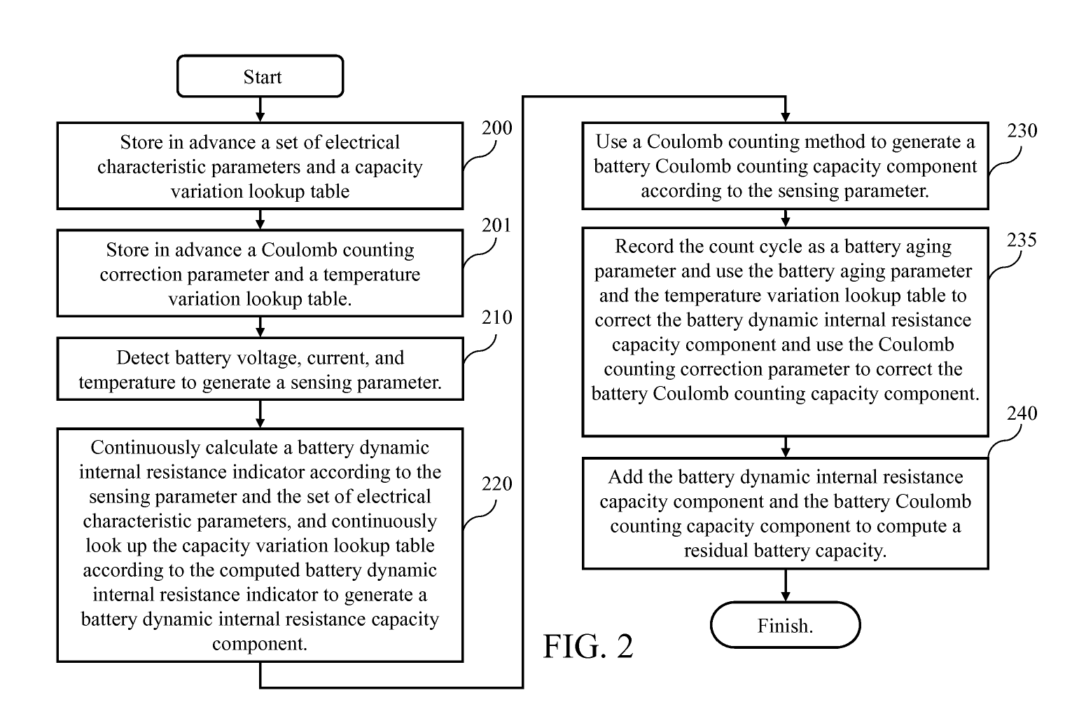

Please refer to FIG. 2 for the flowchart of the disclosed method. The method includes the following steps. Step 200 stores a set of electrical characteristic parameters and a capacity variation lookup table. Step 210 detects the battery voltage, current, temperature to generate sensing parameters. Step 220 continuously uses the sensing parameters and the electrical characteristic parameters to compute a battery dynamic internal resistance indicator, and continuously uses the computed battery dynamic internal resistance indicator to look up the capacity variation lookup table, thereby generating a battery dynamic internal resistance capacity component.

Step 230 uses the sensing parameters to generate a battery Coulomb counting capacity component based on the Coulomb counting method. Step 240 adds the battery dynamic internal resistance capacity component and the battery Coulomb counting capacity component to obtain the actual residual battery capacity. Using the above-mentioned steps, the invention uses the battery voltage, current, and temperature as the sensing parameters. According to predetermined electrical characteristic parameters and the capacity variation lookup table, the sensing parameters are used to compute the battery dynamic internal resistance capacity component. The sensing parameters and the Coulomb counting method are employed to compute the Coulomb counting capacity component. Afterwards, the battery dynamic internal resistance capacity component and the Coulomb counting capacity component are added to obtain the actual residual battery capacity.

In practice, the invention pre-records Coulomb counting correction parameters and a temperature variation lookup table in step 201 and records the cycle count of the battery as a batter aging parameter. The battery aging parameter and the temperature variation lookup table are used to correct the battery dynamic internal resistance capacity component generated in steps 220 and 230. At the same time, the Coulomb counting correction parameters are used to correct the battery Coulomb counting capacity component in step 235. Since the correction method has been previously described, it is not repeated here again.

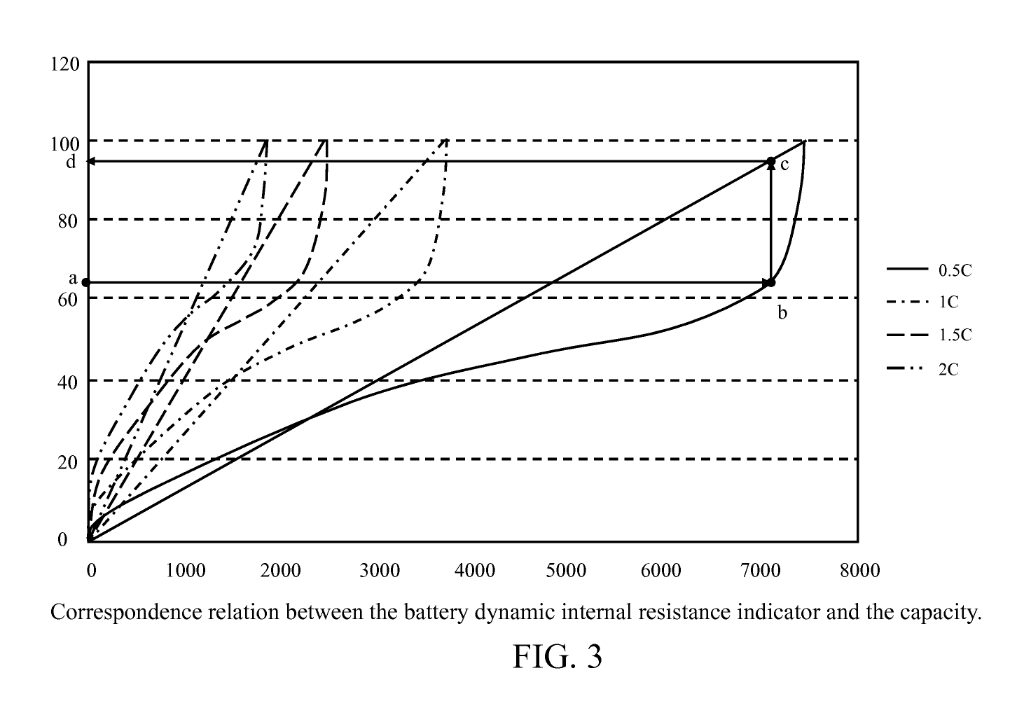

FIGS. 3 through 7 show an explicit embodiment of the invention. FIG. 3 is a schematic view of using the battery dynamic internal resistance indicator to generate the battery dynamic internal resistance capacity component according to the invention. First, the data in the capacity variation lookup table are presented in terms of curves in FIG. 3 (i.e., the correspondence between the battery dynamic internal indicator and the capacity in the time interval from fully charged to fully discharged with different discharge currents). The slant lines give the capacity. The curves are the corresponding battery dynamic internal resistance indicators. In the aforementioned figure, the curves from left to right are the correspondence relationship between the battery dynamic internal resistance indicator and the capacity under the discharge current of 2 C, 1.5 C, 1 C, and 0.5 C, respectively. As previously mentioned, the battery dynamic internal resistance indicator can be obtained using the formula for the battery dynamic internal resistance indicator. To better illustrate this disclosure, the discharge current of 0.5 C is taken as an example. Suppose the calculated battery dynamic internal resistance indicator is point a in FIG. 3. Then point a will correspond to the measured discharge current (i.e., 0.5 C discharge current). Using the capacity variation lookup table in the storage module 100, the correspondence between the battery dynamic internal resistance indicator b and the capacity is found for the discharge current 0.5 C. The discharge capacity thus found is set as c. Then c/0.5 C is used to compute the percentage d of the current capacity in the original total capacity. This percentage is the vertical component (i.e., the battery dynamic internal resistance capacity component). It should be mentioned that although the capacity variation lookup table in FIG. 3 only records four sets of correspondence relations between the battery dynamic internal resistance indicator and the capacity, the invention is not restricted to such a case. In practice, the capacity variation lookup table can also store more sets of correspondence relations between the battery dynamic internal resistance indicator and the capacity at different discharge currents, such as 1.3 C, 1.4 C, etc.

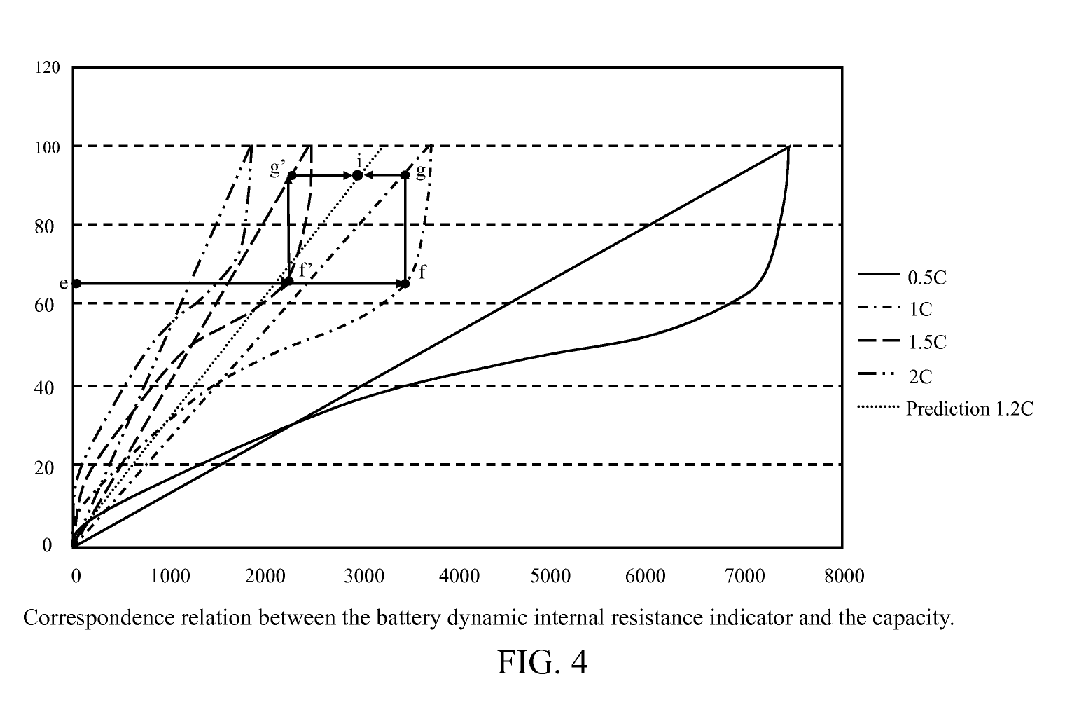

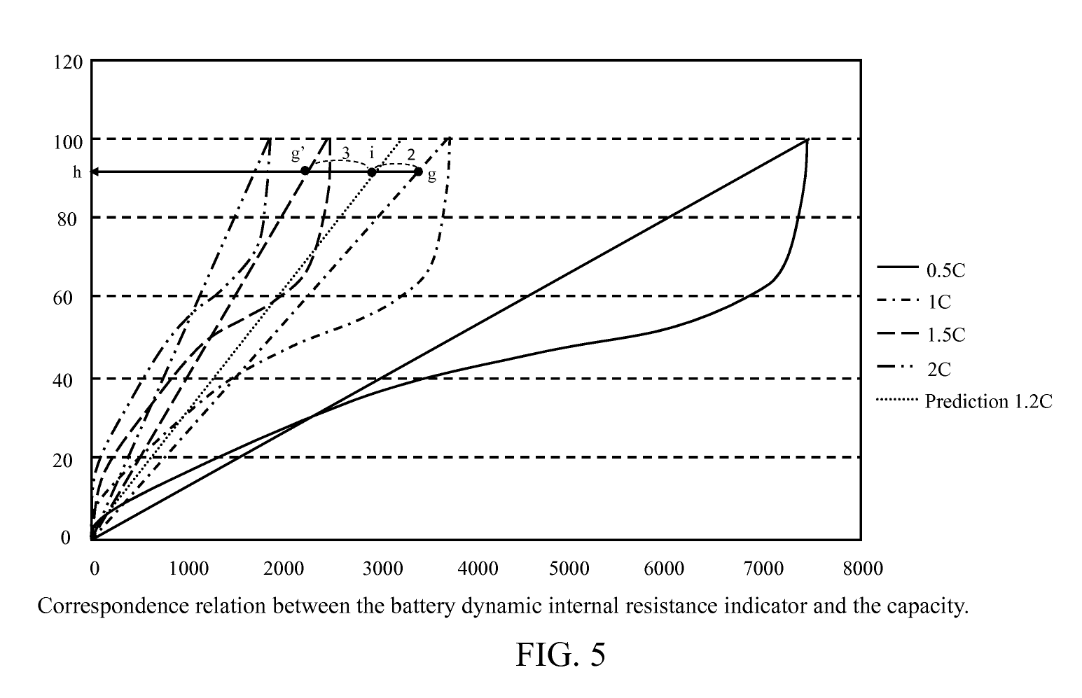

FIGS. 4 and 5 are schematic views of weight processing on intermediate discharge C numbers according to the invention. As previously mentioned, the storage module 100 stores in advance a capacity variation lookup table that records correspondence relations between the battery dynamic internal resistance indicator and the capacity for different discharge C numbers. When the capacity variation lookup table does not have the correspondence relation for the current discharge C number, the invention uses the discharge C numbers before and after it to do a weighting process. For example, suppose the computed battery dynamic internal resistance indicator is “65” (point e in FIG. 4). When the detected discharge C number is 1.2 C and the capacity variation lookup table does not have the correspondence relation between the battery dynamic internal resistance indicator and the capacity for 1.2 C, the invention computes its distances to the discharge C numbers before and after it. That is, the battery dynamic internal resistance indicator “65” is corresponded to point f for 1 C and point f′ for 1.5 C. The discharge capacities point g and point g′ are correspondingly found.

As shown in FIG. 5, the distance between point i of 1.2 C discharge and point g of 1 C discharge is 0.2, and that between point i of 1.2 C discharge and g′ of 1.5 C discharge is 0.3. The ratio of the two is 2:3. Therefore, the capacity percentage is “(3* battery dynamic internal resistance indicator “65” and the capacity for 1 C discharge+2* battery dynamic internal resistance indicator “65” and the capacity for 1.5 C discharge)/(2+3)”. This gives the capacity percentage, point h, corresponding to the battery dynamic internal resistance indicator “65” and a 1.2 C discharge. This percentage is the vertical component (i.e., the battery dynamic internal resistance capacity component).

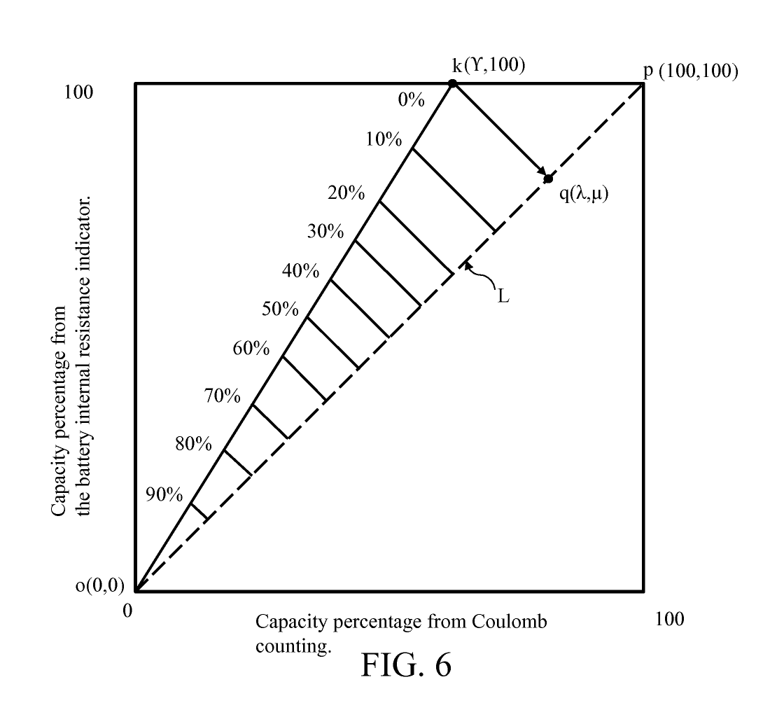

FIG. 6 is a schematic view of defining the residual battery capacity percentage according to the invention. The horizontal axis is the capacity percentage found from the battery Coulomb counting number. The vertical axis is the capacity percentage found from the battery dynamic internal resistance indicator. In the drawing, the relation between the maximum discharge current and the capacity is used to find the coordinates of point k, (γ,100). (As the Coulomb counting method may have deviations from the actual energy consumption because the battery generates heat, the horizontal value cannot reach “100” in practice. The battery dynamic internal resistance indicator makes use of the voltage difference. Therefore, it can definitely reach the position corresponding to the difference between the reference voltage and the lowest threshold voltage. The vertical value can thus reach “100”.) The invention then projects point k onto the track line L. Take the projection “\vec{oq}” of “\vec{Ok}” onto “\vec{op}” as an example. The computation formula is:

$$\vec{oq} = ( \vert \vec{oq} \vert \times cos θ ) \frac{\vec{op}}{\vert \vec{op} \vert} = \frac{\vec{oq} \cdot \vec{op}}{{\vert \vec{op} \vert}^{2}} .$$

This gives the coordinates of point q: (λ,μ). The line segment \vec{oq} between q(λ,μ), and the origin o(0,0) is divided into n equal parts (where n is a positive integer determined according to practical needs and required precision). In FIG. 6, n=100, meaning 100 equal parts. That is, the residual estimate is 100%˜0%, at the precision of 1%. Each part indicates value of the residual battery capacity.

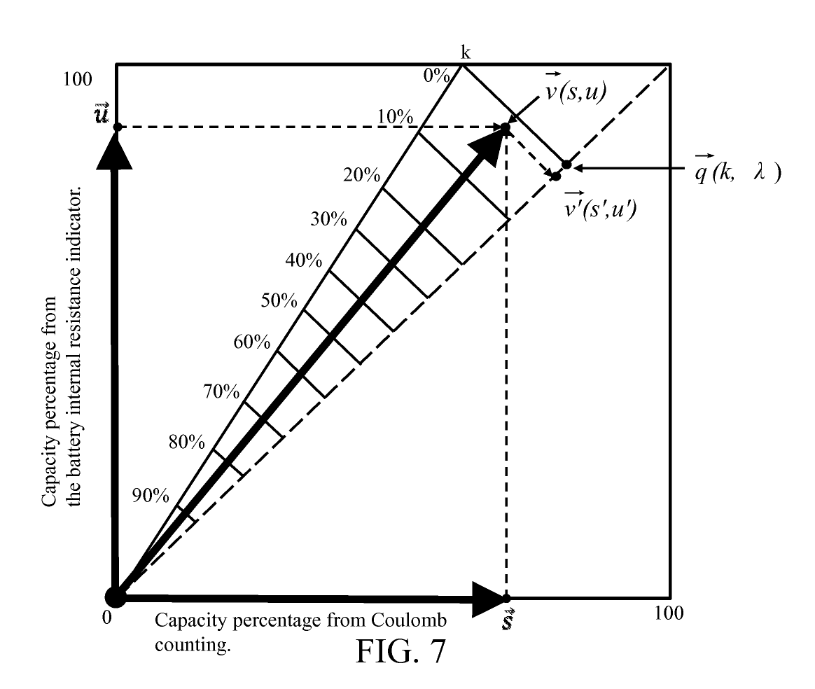

FIG. 7 shows how the invention calculates the residual battery capacity percentage. Suppose at time t the battery dynamic internal resistance indicator gives the capacity percentage “\vec{u}” (i.e., the battery dynamic internal resistance capacity component) and the Coulomb counting method gives the capacity percentage “\vec{s}” (i.e., the battery Coulomb counting capacity component). The vector “\vec{v}(s,u)” defined by the two components projects onto the track line k to obtain “\vec{v′}(s′,u′)”. Afterwards, it is compared with the battery maximum capacity “\vec{q}”. The residual battery capacity percentage is computed as follows:

$$Residual battery capacity \% = \frac{\sqrt{{s}^{′2} + {u}^{′2}}}{\sqrt{{k}^{2} + {λ}^{2}}} .$$

Using the above formula, one can obtain the residual battery capacity percentage at time t. This differs from the prior art that only uses one of the axes for estimates. The invention simultaneously makes corrections on the vertical axis and the horizontal axis to obtain the actual residual battery capacity.

In summary, the invention differs from the prior art in that the invention detects and takes the battery voltage, current and temperature as the sensing parameters. Using predetermined electrical characteristic parameters and the capacity variation lookup table, the invention finds the battery dynamic internal resistance capacity component. The invention also uses the sensing parameters to find the battery Coulomb counting capacity component using the Coulomb counting method. Finally, the invention combines the battery dynamic internal resistance capacity component and the battery Coulomb counting capacity component to obtain the actual residual battery capacity. This technique solves the problems in the prior art and achieves the goal of increasing the accuracy in estimating the residual battery capacity.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A residual battery capacity estimation system that adds two mutually perpendicular components, comprising:
a storage module for storing in advance a set of electrical characteristic parameters and a capacity variation lookup table;
a sensing module for detecting battery voltage, current, and temperature to generate a sensing parameter;
a calculating module for continuously calculating a battery dynamic internal resistance indicator according to the sensing parameter and the set of electrical characteristic parameters, and continuously looking up the capacity variation lookup table according to the computed battery dynamic internal resistance indicator to generate a battery dynamic internal resistance capacity component;
an integrating module for using a Coulomb counting method to generate a battery Coulomb counting capacity component according to the sensing parameter; and
an estimating module for adding the battery dynamic internal resistance capacity component and the battery Coulomb counting capacity component to obtain a residual battery capacity.

2. The system of claim 1, wherein the storage module further stores a Coulomb counting correction parameter and a temperature variation lookup table.

3. The system of claim 2 further comprising a counting module for recording cycle time as a battery aging parameter, wherein the calculating module and the integrating module use the battery aging parameter and the temperature variation lookup table to correct the battery dynamic internal resistance capacity component and use the Coulomb counting correction parameter to correct the battery Coulomb counting capacity component.

4. The system of claim 2, wherein the temperature variation lookup table includes weights for the battery dynamic internal resistance indicator for different discharge currents at different battery temperatures.

5. The system of claim 1, wherein the capacity variation lookup table includes correspondence relations between the battery dynamic internal resistance indicator and the capacity for a plurality of discharge currents.

6. A residual battery capacity estimation method that adds two mutually perpendicular components, comprising the steps of:
storing in advance a set of electrical characteristic parameters and a capacity variation lookup table;
detecting battery voltage, current, and temperature to generate a sensing parameter;
continuously calculating a battery dynamic internal resistance indicator according to the sensing parameter and the set of electrical characteristic parameters, and continuously looking up the capacity variation lookup table according to the computed battery dynamic internal resistance indicator to generate a battery dynamic internal resistance capacity component;
using a Coulomb counting method to generate a battery Coulomb counting capacity component according to the sensing parameter; and
adding the battery dynamic internal resistance capacity component and the battery Coulomb counting capacity component to obtain a residual battery capacity.

7. The method of claim 6 further comprising the step of storing in advance a Coulomb counting correction parameter and a temperature variation lookup table.

8. The method of claim 7 further comprising the step of recording cycle time as a battery aging parameter and using the battery aging parameter and the temperature variation lookup table to correct the battery dynamic internal resistance capacity component and using the Coulomb counting correction parameter to correct the battery Coulomb counting capacity component.

9. The method of claim 7, wherein the temperature variation lookup table includes weights for the battery dynamic internal resistance indicator for different discharge currents at different battery temperatures.

10. The method of claim 6, wherein the capacity variation lookup table includes correspondence relations between the battery dynamic internal resistance indicator and the capacity for a plurality of discharge currents.
